(19) United States
(12) Patent Application Publication
(10) Pub. No.: US 2025/0279765 A1
(43) Pub. Date: Sep. 4, 2025

(54) OPTIMIZATION OF SUPPRESSION OF TRANSVERSE MODE SPURIOUS SIGNALS IN SURFACE ACOUSTIC WAVE FILTERS WHILE MAINTAINING FILTER INSERTION LOSS

(71) Applicant: SKYWORKS SOLUTIONS, INC., Irvine, CA (US)

(72) Inventor: Kyohei Kobayashi, Otsu-Shi (JP)

(21) Appl. No.: 19/063,523

(22) Filed: Feb. 26, 2025

Related U.S. Application Data
(60) Provisional application No. 63/560,141, filed on Mar. 1, 2024.

(51) Int. Cl. H03H 9/64; H03H 3/08

(52) U.S. Cl. CPC H03H 9/6489; H03H 3/08; H03H 9/6483

(57) ABSTRACT

Aspects and embodiments disclosed herein include a radio frequency ladder filter comprising a plurality of series arm surface acoustic wave resonators electrically connected in series between an input of the filter and an output of the filter, and a plurality of shunt surface acoustic wave resonators each electrically connected between nodes between adjacent one of the plurality of series arm surface acoustic wave resonators and ground, one or more of the plurality of series arm surface acoustic wave resonators including gap hammer structures, a remaining one or more of the plurality of series arm surface acoustic wave resonators lacking gap hammer structures to improve insertion loss characteristics of the filter.

### CROSS-REFERENCE TO RELATED APPLICATIONS

This application claims priority under 35 U.S.C. § 119 (e) to U.S. Provisional Patent Application Ser. No. 63/560,141, titled “OPTIMIZATION OF SUPPRESSION OF TRANSVERSE MODE SPURIOUS SIGNALS IN SURFACE ACOUSTIC WAVE FILTERS WHILE MAINTAINING FILTER INSERTION LOSS,” filed Mar. 1, 2024, the entire content of which is incorporated herein by reference for all purposes.

### BACKGROUND

### Technical Field

Embodiments of this disclosure relate to radio frequency filters including acoustic wave devices and to suppression of transverse mode spurious signals and improvement in insertion loss in same.

### Description of Related Technology

Acoustic wave devices, for example, surface acoustic wave (SAW) and bulk acoustic wave (BAW) devices may be utilized as components of filters in radio frequency electronic systems. For instance, filters in a radio frequency front-end of a mobile phone can include acoustic wave filters. Two acoustic wave filters can be arranged as a duplexer.

### SUMMARY

In accordance with one aspect, there is provided a radio frequency ladder filter. The radio frequency ladder filter comprises a plurality of series arm surface acoustic wave resonators electrically connected in series between an input of the filter and an output of the filter, and a plurality of shunt surface acoustic wave resonators each electrically connected between nodes between adjacent one of the plurality of series arm surface acoustic wave resonators and ground, one or more of the plurality of series arm surface acoustic wave resonators including gap hammer structures, a remaining one or more of the plurality of series arm surface acoustic wave resonators lacking gap hammer structures to improve insertion loss characteristics of the filter.

In some embodiments, one or more of the plurality of shunt surface acoustic wave resonators include gap hammer structures.

In some embodiments, each of the plurality of shunt surface acoustic wave resonators include gap hammer structures.

In some embodiments, one of the plurality of series arm surface acoustic wave resonators has a resonance frequency lower than another of the plurality of series arm surface acoustic wave resonators, the one of the plurality of series arm surface acoustic wave resonators including the gap hammer structure, the another of the plurality of series arm surface acoustic wave resonators lacking the gap hammer structure.

In some embodiments, the plurality of series arm surface acoustic wave resonators have a respective plurality of resonance frequencies, at least one of the plurality of series arm surface acoustic wave resonators having a lower resonance frequency than at least one other of the plurality of series arm surface acoustic wave resonators including the gap hammer structure.

In some embodiments, a series arm surface acoustic wave resonator having a lowest resonance frequency among the plurality of series arm surface acoustic wave resonators includes the gap hammer structure.

In some embodiments, a series arm surface acoustic wave resonator having a highest resonance frequency among the plurality of series arm surface acoustic wave resonators lacks the gap hammer structure.

In some embodiments, a plurality of series arm surface acoustic wave resonators having lower resonance frequencies than a series arm surface acoustic wave resonators having a highest resonance frequency among the plurality of series arm surface acoustic wave resonators include the gap hammer structure.

In accordance with another aspect, there is provided Aan electronics module comprising a radio frequency ladder filter including a plurality of series arm surface acoustic wave resonators electrically connected in series between an input of the filter and an output of the filter, and a plurality of shunt surface acoustic wave resonators each electrically connected between nodes between adjacent one of the plurality of series arm surface acoustic wave resonators and ground, one or more of the plurality of series arm surface acoustic wave resonators including gap hammer structures, a remaining one or more of the plurality of series arm surface acoustic wave resonators lacking gap hammer structures to improve insertion loss characteristics of the filter.

In some embodiments, one or more of the plurality of shunt surface acoustic wave resonators include gap hammer structures.

In some embodiments, each of the plurality of shunt surface acoustic wave resonators include gap hammer structures.

In some embodiments, one of the plurality of series arm surface acoustic wave resonators has a resonance frequency lower than another of the plurality of series arm surface acoustic wave resonators, the one of the plurality of series arm surface acoustic wave resonators including the gap hammer structure, the another of the plurality of series arm surface acoustic wave resonators lacking the gap hammer structure.

In some embodiments, the plurality of series arm surface acoustic wave resonators have a respective plurality of resonance frequencies, at least one of the plurality of series arm surface acoustic wave resonators having a lower resonance frequency than at least one other of the plurality of series arm surface acoustic wave resonators including the gap hammer structure.

In some embodiments, a series arm surface acoustic wave resonator having a lowest resonance frequency among the plurality of series arm surface acoustic wave resonators includes the gap hammer structure.

In some embodiments, a series arm surface acoustic wave resonator having a highest resonance frequency among the plurality of series arm surface acoustic wave resonators lacks the gap hammer structure.

In some embodiments, a plurality of series arm surface acoustic wave resonators having lower resonance frequencies than a series arm surface acoustic wave resonators having a highest resonance frequency among the plurality of series arm surface acoustic wave resonators include the gap hammer structure.

In accordance with another aspect, there is provided a method of forming a radio frequency ladder filter. The method comprises forming a plurality of surface acoustic waver resonators, one or more of the surface acoustic wave resonators including a gap hammer structure, one or more other of the surface acoustic wave resonators lacking a gap hammer structure, electrically connecting a first subset of the plurality of surface acoustic wave resonators in series between an input and an output of the filter, at least one of the first subset of the plurality of surface acoustic wave resonators lacking the gap hammer structure, and electrically connecting a second subset of the plurality of surface acoustic wave resonators between nodes between adjacent one of the first subset of the plurality of series arm surface acoustic wave resonators and ground.

In some embodiments, at least one of the second subset of the plurality of surface acoustic wave resonators includes a gap hammer structure.

In some embodiments, at least one of the first subset of the plurality of surface acoustic wave resonators having a resonance frequency lowest among the first subset of the plurality of surface acoustic wave resonators includes a gap hammer structure.

In some embodiments, at least one of the first subset of the plurality of surface acoustic wave resonators having a resonance frequency highest among the first subset of the plurality of surface acoustic wave resonators lacks a gap hammer structure.

### BRIEF DESCRIPTION OF THE DRAWINGS

Embodiments of this disclosure will now be described, by way of non-limiting example, with reference to the accompanying drawings.

FIG. 1A is a simplified plan view of an example of a surface acoustic wave resonator;

FIG. 1B is a simplified plan view of another example of a surface acoustic wave resonator;

FIG. 1C is a simplified plan view of another example of a surface acoustic wave resonator;

FIG. 2A is a plan view of a portion of electrodes of a surface acoustic wave filter including a structure for suppressing transverse mode spurious signals;

FIG. 2B is a cross-sectional view of a portion of electrodes of a surface acoustic wave resonator including a structure for suppressing transverse mode spurious signals;

FIG. 3 illustrates transverse spurious mode signals generated in a SAW resonator including IDT electrodes with a molybdenum layer;

FIG. 4 illustrates transverse spurious mode signals generated in a SAW resonator including IDT electrodes with a tungsten layer;

FIG. 5 illustrates an example of IDT electrode extensions in a gap region of a SAW resonator;

FIG. 6 illustrates another example of IDT electrode extensions in a gap region of a SAW resonator;

FIG. 7 illustrates a comparison between the insertion loss curves of ladder filters formed with SAW resonators as shown in partial view in FIG. 2A (without IDT electrode extensions) and SAW resonators as shown in partial view in FIG. 5 (with IDT electrode extensions);

FIG. 8A illustrates a ladder filter formed of SAW resonators in which some of the SAW resonators include IDT electrode extensions (“gap hammers”) and some do not;

FIG. 8B illustrates a comparison between the insertion loss curves of ladder filters formed with SAW resonators as shown in partial view in FIG. 2A (without IDT electrode extensions) and a ladder filter as shown in FIG. 8A;

FIG. 9A illustrates another ladder filter formed of SAW resonators in which some of the SAW resonators include IDT electrode extensions (“gap hammers”) and some do not;

FIG. 9B illustrates a comparison between the insertion loss curves of a ladder filter as shown in FIG. 8A and a ladder filter as shown in FIG. 9A;

FIG. 10A illustrates another ladder filter formed of SAW resonators in which some of the SAW resonators include IDT electrode extensions (“gap hammers”) and some do not;

FIG. 10B illustrates another ladder filter formed of SAW resonators in which some of the SAW resonators include IDT electrode extensions (“gap hammers”) and some do not;

FIG. 10C illustrates another ladder filter formed of SAW resonators in which some of the SAW resonators include IDT electrode extensions (“gap hammers”) and some do not;

FIG. 11 is a block diagram of one example of a filter module that can include one or more surface acoustic wave filters according to aspects of the present disclosure;

FIG. 12 is a block diagram of one example of a front-end module that can include one or more filter modules according to aspects of the present disclosure; and

FIG. 13 is a block diagram of one example of a wireless device including the front-end module of FIG. 12.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

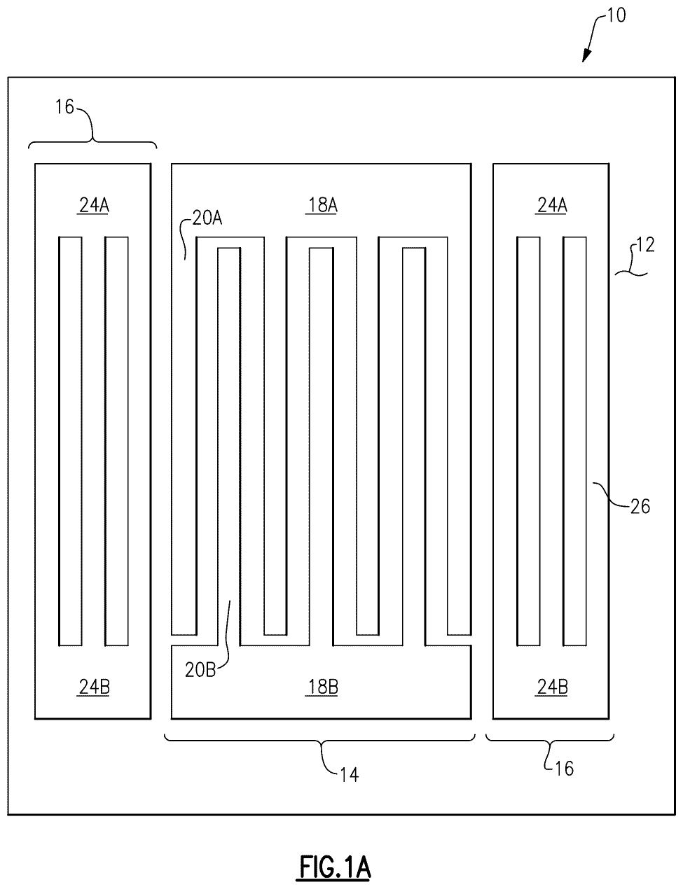

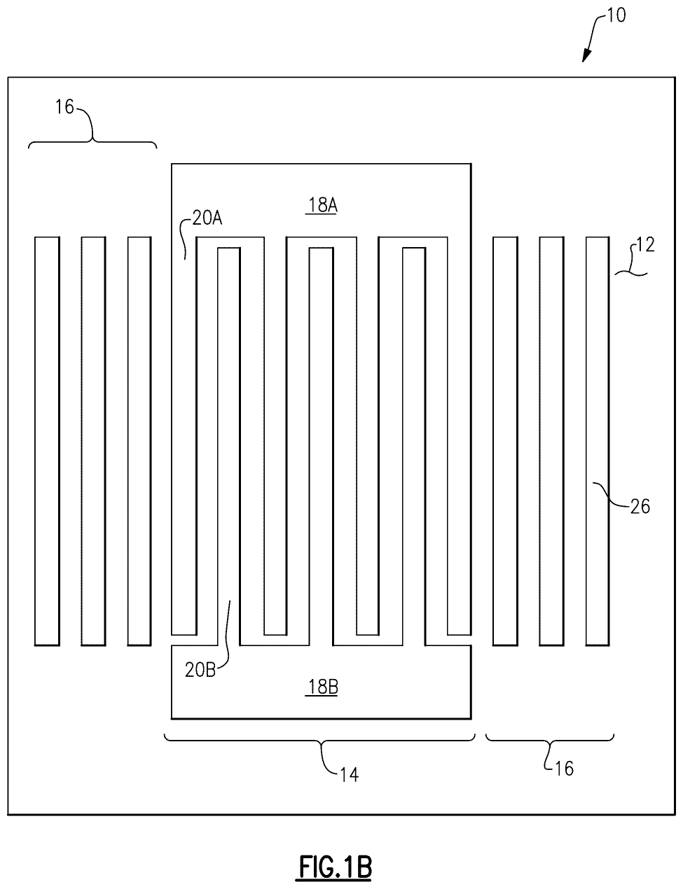

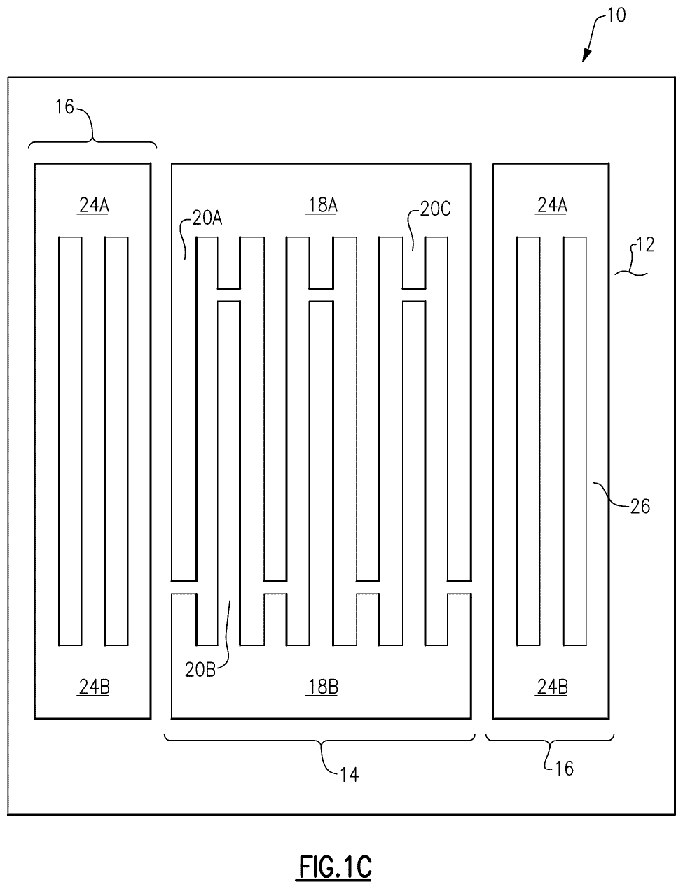

FIG. 1A is a plan view of a surface acoustic wave (SAW) resonator 10 such as might be used in a SAW filter, duplexer, etc.

Acoustic wave resonator 10 is formed on a substrate 12 including a piezoelectric material layer, for example, a lithium tantalate (LiTaO₃) or lithium niobate (LiNbO₃) material layer. In some embodiments the substrate 12 may be a multilayer piezoelectric substrate (MPS). The acoustic wave resonator 10 includes Interdigital Transducer (IDT) electrodes 14 and reflector electrodes 16. In use, the IDT electrodes 14 excite a main acoustic wave having a wavelength 2 along a surface of the substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first bus bar electrode 18A and a second bus bar electrode 18B facing the first bus bar electrode 18A. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings) each include a first reflector bus bar electrode 24A and a second reflector bus bar electrode 24B and reflector fingers 26 extending between and electrically coupling the first bus bar electrode 24A and the second bus bar electrode 24B.

In other embodiments disclosed herein, as illustrated in FIG. 1B, the reflector bus bar electrodes 24A, 24B may be omitted and the reflector fingers 26 may be electrically unconnected. Further, as illustrated in FIG. 1C, acoustic wave resonators as disclosed herein may include dummy electrode fingers 20C that are aligned with respective electrode fingers 20A, 20B. Each dummy electrode finger 20C extends from the opposite bus bar electrode 18A, 18B than the respective electrode finger 20A, 20B with which it is aligned.

It should be appreciated that the acoustic wave resonators 10 illustrated in FIGS. 1A-1C, as well as the other circuit elements illustrated in other figures presented herein, are illustrated in a highly simplified form. The relative dimensions of the different features are not shown to scale. Further, typical acoustic wave resonators would commonly include a far greater number of electrode fingers and reflector fingers than illustrated. Typical acoustic wave resonators or filter elements may also include multiple IDT electrodes sandwiched between the reflector electrodes.

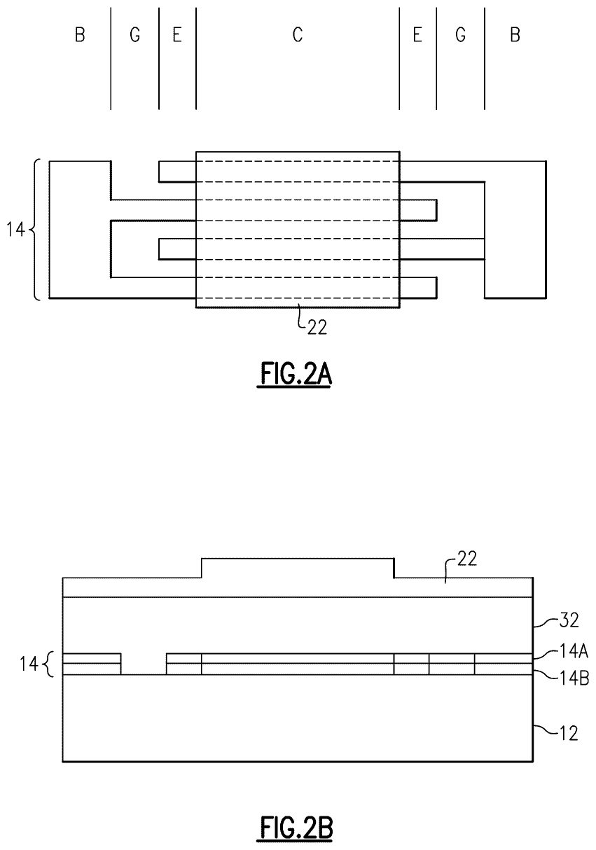

As illustrated in FIG. 2A, regions along lengths of the IDT electrodes of a SAW device, e.g., a SAW resonator, may be characterized as busbar regions “B” including the busbar portions of the IDT electrodes, gap regions “G” between the busbar of a first set of IDT electrodes and the ends of the fingers of a second set of IDT electrode extending from a second busbar of the SAW device, edge regions “E” including end portions of the IDT electrodes, and a center region “C” sandwiched between the edge regions. In some embodiments, the gap regions may have widths of between about 1λ and 1.5λ, the edge regions may have widths of between about 0.25λ and 1.25λ, and the center region may have a width of about 20λ, although it should be understood that these dimensions are only examples and may vary based on the design of a particular resonator. In some embodiments, a layer of a dielectric 22 exhibiting a high acoustic wave velocity, for example, silicon nitride (Si₃N₄, also abbreviated as “SiN” herein) may be disposed over the IDT electrodes within the center region C. In some embodiments, as illustrated in FIG. 2B, the layer of high acoustic wave velocity material 22 may be deposited over a dielectric material 32 having a lower acoustic wave velocity, for example, silicon dioxide (SiO₂) disposed over the entire IDT electrode structure (regions B, G, E, and D). The layer of high acoustic wave velocity material 22 may include a thicker portion disposed in the center region C than in the other regions B, G, and E. The layer of high acoustic wave velocity material 22 disposed over the IDT electrodes in the center region C may help to confine acoustic waves to the center region C and reduce the amount of acoustic energy that travels outside of this region in a direction perpendicular to that of the propagation direction of the main acoustic wave in the device and that may cause transverse mode spurious signals in the frequency response of the SAW device. The main acoustic wave of the device travels perpendicular to the lengthwise direction of the IDT electrodes and the transverse mode spurious signals may be caused by acoustic waves travelling parallel to the lengthwise direction of the IDT electrodes.

The SiO₂ layer 32 may have a negative temperature coefficient of frequency, which helps to offset the positive temperature coefficient of frequency of the piezoelectric substrate 12 and reduce the change in frequency response of the SAW device with changes in temperature. A SAW device with a layer of SiO₂ over the IDT electrodes may thus be referred to as a temperature-compensated SAW device, or TCSAW.

As also illustrated in FIG. 2B, the IDT electrodes 14 may be layered electrodes including an upper layer 14A of a highly conductive but low-density material, for example, aluminum (Al), and a lower layer 14B of a less conductive, but more dense material, for example, molybdenum (Mo) or tungsten (W). The denser lower layer 14B may reduce the acoustic velocity of acoustic waves travelling through the device which may allow the IDT electrode fingers to be spaced more closely for a given operating frequency and allow the SAW device to be reduced in size as compared to a similar device utilizing less dense IDT electrodes. The less dense upper layer 14A may have a higher conductivity than the lower layer 14B to provide the electrode stack with a lower overall resistivity.

Consumers and device manufacturers continue to demand electronic products such as cellular telephones with smaller form factors and/or that include additional functionality. Accordingly, there is a continuing demand for smaller and smaller electronic components used in these electronic products, for example, SAW resonators and filters that are incorporated in same. A method of decreasing the size of a SAW resonator while maintaining the operating frequency of the SAW resonator includes increasing the density of the IDT electrodes of the SAW resonator. Higher density IDT electrodes result in a reduced velocity and reduced wavelength of acoustic waves generated in the SAW resonator, which allows denser IDT electrodes to be spaced closer to each other than less dense IDT electrodes to achieve the same operating frequency. In many examples of previously and currently available SAW resonators, the IDT electrodes were formed of Mo, often with a layer of Al on top of the Mo to increase the conductivity of the IDT electrodes. To increase the density of the IDT electrodes, the Mo layer of the IDT electrodes may be replaced with a layer of a higher density material, for example, W.

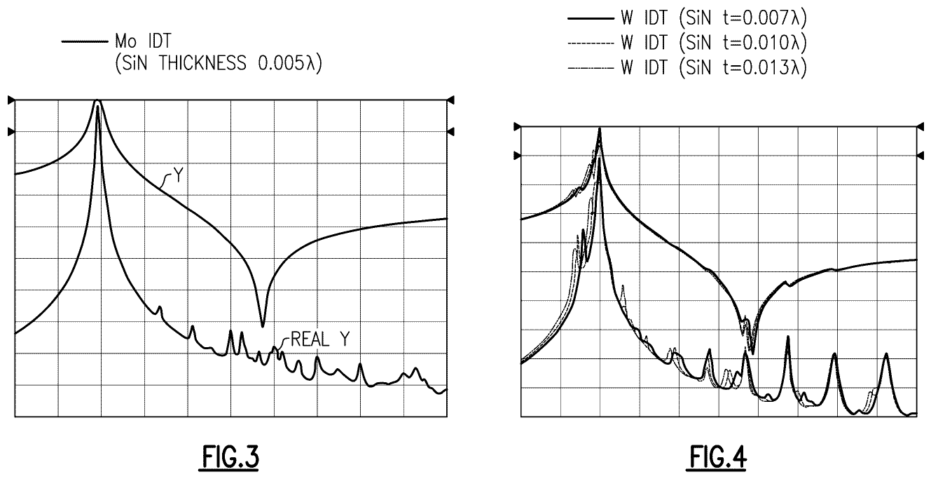

It has been discovered that when the Mo layer in IDT electrodes of examples of SAW resonators is replaced with W, previously utilized structures, such as the layer of high acoustic wave velocity material 22 disposed over the IDT electrodes in their center region C, may be less effective than desirable in suppressing transverse mode spurious signals that may interfere with operation of the SAW resonator. FIG. 3 illustrates the strength of transverse mode spurious signals generated in a SAW resonator utilizing IDT electrodes with a Mo layer and a silicon nitride layer thickness of 0.005λ, where λ represents the wavelength of the main acoustic wave generated in the resonator. In comparison, FIG. 4 illustrates the strength of transverse mode spurious signals generated in a similar SAW resonator utilizing IDT electrodes with a W layer and various silicon nitride layer thickness. It can be seen that even if the thickness of the silicon nitride layer is more than doubled in the SAW resonator utilizing the IDT electrodes with the W layer as compared to that of the SAW resonator utilizing the IDT electrodes with the Mo layer, the transverse mode spurious signals generated in the SAW resonator utilizing the IDT electrodes with the W layer are significantly stronger than the transverse mode spurious signals generated in the SAW resonator utilizing the IDT electrodes with the Mo layer.

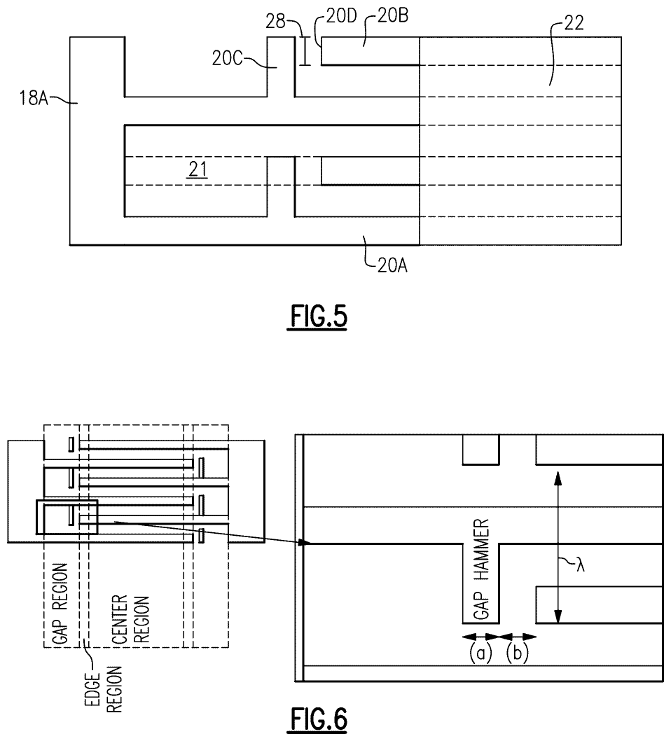

One method of reducing the strength of transverse mode spurious signals in a SAW resonator may be to include additional material, for example, extensions of the IDT electrodes in the gap regions of the SAW resonator. FIG. 5 illustrates one example of a SAW resonator including extensions 20C of the IDT electrodes in the gap regions of the resonator. Only the region proximate one of the busbars 18A and extensions 20C from only one set 20A of IDT electrodes is illustrated. It is to be appreciated that the same form of IDT electrode extensions 20C may be present in the gap region on the unillustrated side of the resonator extending from the second set 20B of IDT electrodes (See FIG. 6 below). The resonator may include the layer of high acoustic wave velocity material 22 over the IDT electrodes in the center region of the resonator and, in some embodiments, the layer of dielectric material 32 below the layer of material 22 as well. The IDT electrode extensions 20C may be referred to herein as “gap hammers.”

The IDT electrode extensions 20C in the gap region of the resonator may be in the form of rectangles of the same material or materials that the IDT electrodes are formed of that extend perpendicular to the lengthwise direction of the IDT electrodes. In some embodiments, the IDT electrode extensions 20C from one set of IDT electrodes 20A may extend to a position overlapping an extending region 21 of tips 20D of the other set of IDT electrodes 20B to define an overlap region 28. The extending region 21 may be defined by lines extending into the gap region from opposite lengthwise sides of the other set of IDT electrodes 20B in the edge region (and on the other side of the resonator, from the sides of the set of IDT electrodes 20A in the edge region).

In some embodiments, the IDT electrode extensions 20C may extend through and terminate at ends of the extending regions 21 and overlap an entirety of the widths of the tips 20D of the other set of IDT electrodes 20B, in other embodiments, may extend only partially through the extending regions 21 and only partially overlap the widths of the tips 20D of the other set of IDT electrodes 20B, and in other embodiments, the IDT electrode extensions 20C may extend beyond the edges of the extension regions 21 and beyond the tips 20D of the other set of IDT electrodes 20B. Unless specified otherwise, as the term is used herein, a width direction is in a direction parallel to the direction of propagation of the main acoustic wave through the SAW resonator. Unless specified otherwise, as the term is used herein, a lengthwise direction is perpendicular to the direction of propagation of the main acoustic wave through the SAW resonator.

Although illustrated as rectangular structures extending from only a single side of the IDT electrodes 20A in FIG. 5, in other embodiments, the IDT electrode extensions 20C may extend from both sides of the IDT electrodes 20A (and/or IDT electrodes 20B). It should be appreciated that the IDT electrode extensions 20C are not limited to having a rectangular shape. In other embodiments, the IDT electrode extensions 20C may be square, oval, circular, or may have any other shape desired.

The gap hammers 20C may have lengthwise dimensions (a) as shown in FIG. 6 that may be between 0.10λ and 0.30λ. The gap hammers 20C may be spaced from tips of opposing electrode fingers by a distance (b) of between 0.10λ and 0.30λ. In some embodiments, lengths (a) and (b) are equal so that a “gap hammer duty factor” of a/(a+b)=0.50.

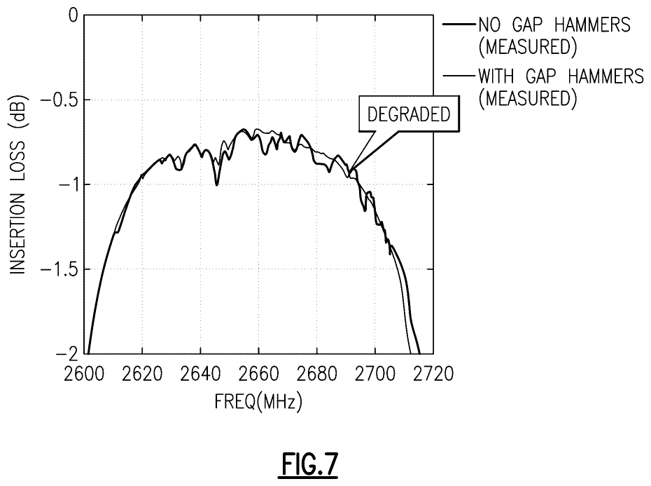

As noted above the gap hammers 20C may help suppress transverse mode spurious signals in the admittance curve of a SAW resonator. However, the gap hammers 20C may also reduce the quality factor of the resonator, which may manifest as deterioration of the insertion loss curve for a ladder filter formed of SAW resonators including the gap hammers. FIG. 7 illustrates a comparison between the measured insertion loss curve of a ladder filter formed of SAW resonators without gap hammers such as illustrated in part in FIG. 2A and a ladder filter formed of SAW resonators including gap hammers such as illustrated in part in FIG. 5. It can be observed that the ladder filter formed of the SAW resonators including the gap hammers exhibits a slight degradation in insertion loss at the upper end of the passband.

To at least partially alleviate the degradation in insertion loss of a ladder filter due to the presence of the gap hammers in the SAW resonators forming the filter while retaining at least some, if not most, of the benefit of reduced spurious signals in resonator admittance curves due to the gap hammers, one may form the ladder filter with some of the SAW resonators including the gap hammers and some of the SAW resonators not including the gap hammers, for example, with some of the resonators having IDT structures as illustrated in part in FIG. 2A and others of the resonators including IDT structures as illustrated in FIG. 5.

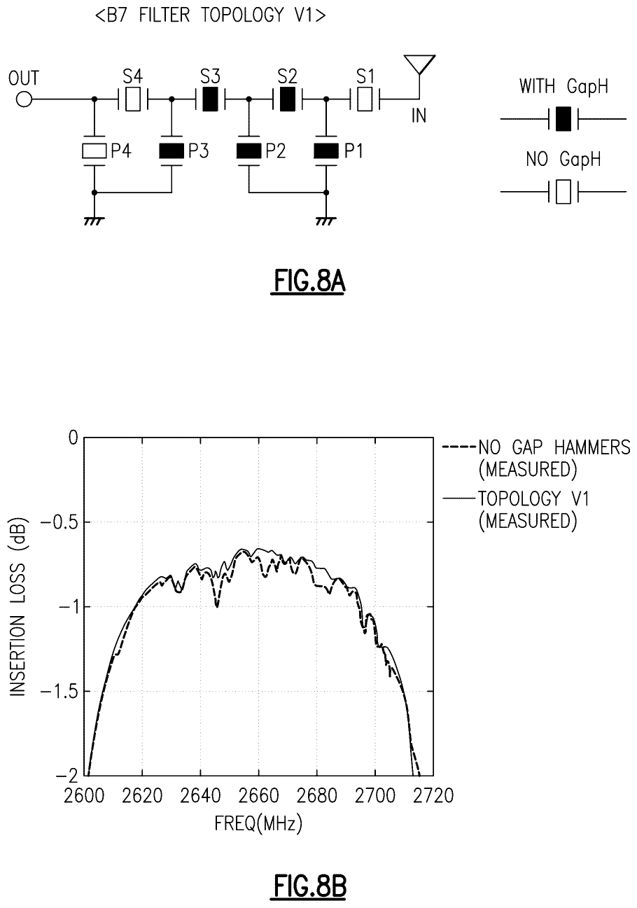

FIG. 8A illustrates one example of a ladder filter (“B7 Filter Topology v1”) including four series arm resonators and four shunt resonators. Two out of four of the series arm resonators include gap hammer structures (“With GapH”) while the other two do not (“No GapH”). Three out of four of the shunt resonators include gap hammer structures while one does not. FIG. 8B compares the measured insertion loss curve for the ladder filter of FIG. 8A against a ladder filter with a similar layout but in which all resonators lack gap hammer structures. The insertion loss curve for the “B7 Filter Topology v1” ladder filter is improved as compared to that of the ladder filter with all resonators lacking gap hammer structures.

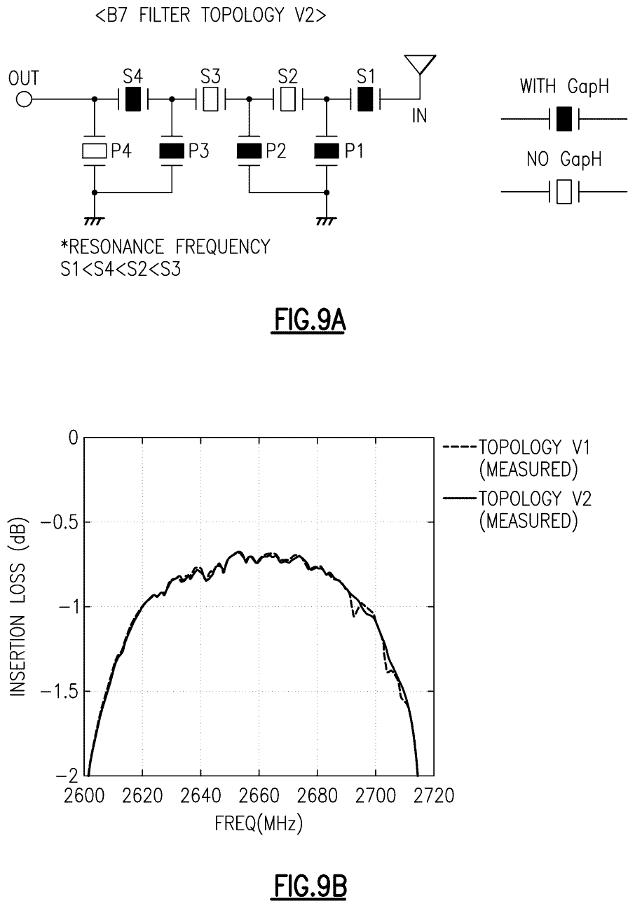

It has been discovered that even further improvements in filter insertion loss may be achieved if the series arm resonators including the gap hammer structures were selected from the series arm resonators with lower resonance frequencies and series arm resonators without the gap hammer structures were selected from the series arm resonators with higher resonance frequencies. As illustrated in FIG. 9A a ladder filter (“B7 Filter Topology v2”) includes series arm resonators S1, S2, S3, S4, each with different resonance frequencies. Resonator S1 has the lowest resonance frequency, S4 has the second lowest resonance frequency, S2 the second highest resonance frequency, and S3 has the highest resonance frequency. Gap hammer structures are included in the two series arm resonators with the lower resonance frequencies, namely S1 and S4, while the two series arm resonators with the higher resonance frequencies, namely S2 and S3 do not include gap hammer structures. Shunt resonators P1, P2, and P3 include gap hammer structures while shunt resonator P4 does not.

FIG. 9B compares the measured insertion loss curve of the ladder filter with the v2 topology as illustrated in FIG. 9A against the ladder filter with the v1 topology as illustrated in FIG. 8A. It can be seen that the ladder filter with the v2 topology as illustrated in FIG. 9A exhibits an improved insertion loss curve, especially on the high frequency side, as compared to the ladder filter with the v1 topology as illustrated in FIG. 8A.

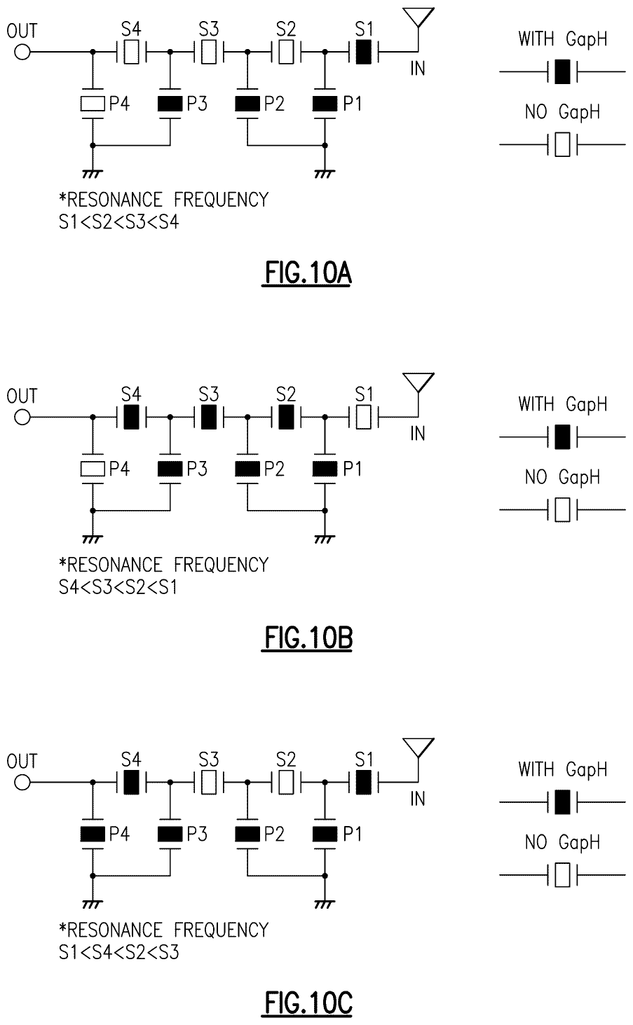

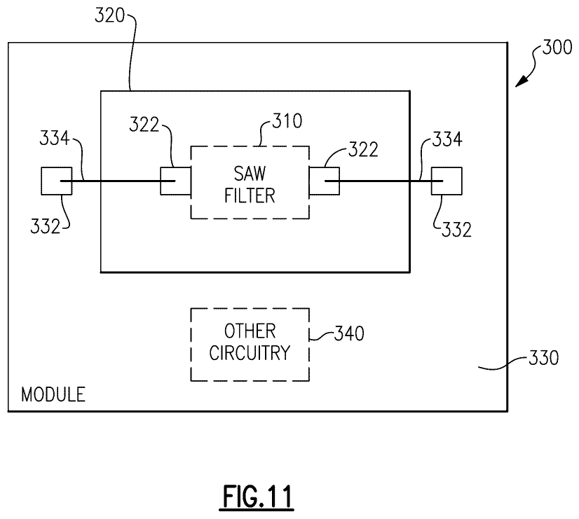

It should be noted that the positions of the series arm resonators with the higher and lower resonance frequencies need not be as shown in FIG. 9A. Any of the series arm resonators may have the highest resonance frequency, any other of the series arm resonators may have the second highest resonance frequency, any other of the series arm resonators may have the second lowest resonance frequency, and any other of the series arm resonators may have the lowest resonance frequency among the group of series arm resonators. Furthermore, in different embodiments, a ladder filter may include a different number of series arm resonators with gap hammer structures. As an example, FIG. 10A illustrates a ladder filter in which only the series arm resonator S1 with the lowest resonance frequency among the series arm resonators includes a gap hammer structure. FIG. 10B illustrates an embodiment in which all series arm resonators except the one having the highest resonance frequency, namely S1, include gap hammer structures. In other embodiments, any of the shunt resonators may include or not include gap hammer structures. FIG. 10C illustrates an example of a ladder filter similar to that of FIG. 9A but in which all of the shunt resonators include gap hammer structures. In further embodiments, ladder filters may include more or fewer series arm and/or shunt resonators than illustrated in the examples depicted herein.

Filter including SAW resonators with and without gap hammer structures as discussed herein can be implemented in a variety of packaged modules. Some example packaged modules will now be discussed in which any suitable principles and advantages of the filters discussed herein can be implemented. FIGS. 11, 12, and 13 are schematic block diagrams of illustrative packaged modules and devices according to certain embodiments.

As discussed above, embodiments of a surface acoustic wave (SAW) filter using one or more surface acoustic wave elements may be incorporated into and packaged as a module that may ultimately be used in an electronic device, such as a wireless communications device, for example. FIG. 11 is a block diagram illustrating one example of a module 300 including a SAW filter 310. The SAW filter 310 may be implemented on one or more die(s) 320 including one or more connection pads 322. For example, the SAW filter 310 may include a connection pad 322 that corresponds to an input contact for the SAW filter and another connection pad 322 that corresponds to an output contact for the SAW filter. The packaged module 300 includes a packaging substrate 330 that is configured to receive a plurality of components, including the die 320. A plurality of connection pads 332 can be disposed on the packaging substrate 330, and the various connection pads 322 of the SAW filter die 320 can be connected to the connection pads 332 on the packaging substrate 330 via electrical connectors 334, which can be solder bumps or wirebonds, for example, to allow for passing of various signals to and from the SAW filter 310. The module 300 may optionally further include other circuitry die 340, for example, one or more additional filter(s), amplifiers, pre-filters, modulators, demodulators, down converters, and the like, as would be known to one of skill in the art of semiconductor fabrication in view of the disclosure herein. In some embodiments, the module 300 can also include one or more packaging structures to, for example, provide protection and facilitate easier handling of the module 300. Such a packaging structure can include an overmold formed over the packaging substrate 330 and dimensioned to substantially encapsulate the various circuits and components thereon.

Various examples and embodiments of the SAW filter 310 can be used in a wide variety of electronic devices. For example, the SAW filter 310 can be used in an antenna duplexer, which itself can be incorporated into a variety of electronic devices, such as RF front-end modules and communication devices.

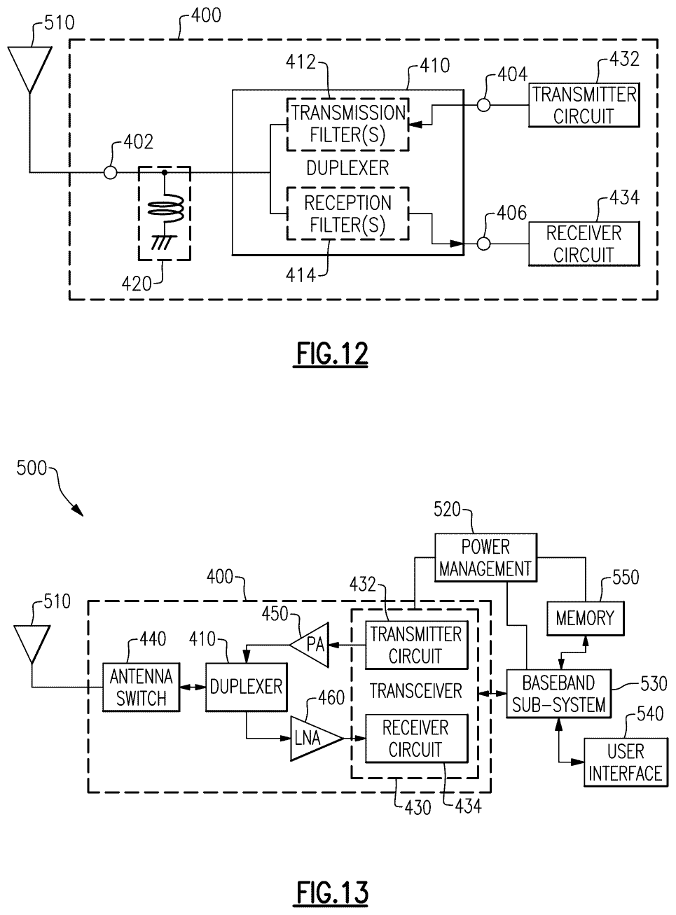

Referring to FIG. 12, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filters. Examples of the SAW filter 310 can be used to form the transmission filter(s) 412 and/or the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 510. In some embodiments, the receiver and transmitter circuits are implemented as separate components, as shown in FIG. 12, however in other embodiments these components may be integrated into a common transceiver circuit or module. As will be appreciated by those skilled in the art, the front-end module 400 may include other components that are not illustrated in FIG. 12 including, but not limited to, switches, electromagnetic couplers, amplifiers, processors, and the like.

FIG. 13 is a block diagram of one example of a wireless device 500 including the antenna duplexer 410 shown in FIG. 12. The wireless device 500 can be a cellular phone, smart phone, tablet, modem, communication network or any other portable or non-portable device configured for voice or data communication. The wireless device 500 can receive and transmit signals from the antenna 510. The wireless device includes an embodiment of a front-end module 400 similar to that discussed above with reference to FIG. 12. The front-end module 400 includes the duplexer 410, as discussed above. In the example shown in FIG. 13 the front-end module 400 further includes an antenna switch 440, which can be configured to switch between different frequency bands or modes, such as transmit and receive modes, for example. In the example illustrated in FIG. 13, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 12.

Signals generated for transmission by the transmitter circuit 432 are received by a power amplifier (PA) module 450, which amplifies the generated signals from the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 13, the front-end module 400 may further include a low noise amplifier module 460, which amplifies received signals from the antenna 510 and provides the amplified signals to the receiver circuit 434 of the transceiver 430.

The wireless device 500 of FIG. 13 further includes a power management sub-system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHZ, such as in a range from about 600 MHz to 2.7 GHZ.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A radio frequency ladder filter comprising:
a plurality of series arm surface acoustic wave resonators electrically connected in series between an input of the filter and an output of the filter; and
a plurality of shunt surface acoustic wave resonators each electrically connected between nodes between adjacent one of the plurality of series arm surface acoustic wave resonators and ground, one or more of the plurality of series arm surface acoustic wave resonators including gap hammer structures, a remaining one or more of the plurality of series arm surface acoustic wave resonators lacking gap hammer structures to improve insertion loss characteristics of the filter.

2. The radio frequency ladder filter of claim 1 wherein one or more of the plurality of shunt surface acoustic wave resonators include gap hammer structures.

3. The radio frequency ladder filter of claim 2 wherein each of the plurality of shunt surface acoustic wave resonators include gap hammer structures.

4. The radio frequency ladder filter of claim 1 wherein one of the plurality of series arm surface acoustic wave resonators has a resonance frequency lower than another of the plurality of series arm surface acoustic wave resonators, the one of the plurality of series arm surface acoustic wave resonators including the gap hammer structure, the another of the plurality of series arm surface acoustic wave resonators lacking the gap hammer structure.

5. The radio frequency ladder filter of claim 1 wherein the plurality of series arm surface acoustic wave resonators have a respective plurality of resonance frequencies, at least one of the plurality of series arm surface acoustic wave resonators having a lower resonance frequency than at least one other of the plurality of series arm surface acoustic wave resonators including the gap hammer structure.

6. The radio frequency ladder filter of claim 5 wherein a series arm surface acoustic wave resonator having a lowest resonance frequency among the plurality of series arm surface acoustic wave resonators includes the gap hammer structure.

7. The radio frequency ladder filter of claim 5 wherein a series arm surface acoustic wave resonator having a highest resonance frequency among the plurality of series arm surface acoustic wave resonators lacks the gap hammer structure.

8. The radio frequency ladder filter of claim 5 wherein a plurality of series arm surface acoustic wave resonators having lower resonance frequencies than a series arm surface acoustic wave resonators having a highest resonance frequency among the plurality of series arm surface acoustic wave resonators include the gap hammer structure.

9. An electronics module comprising a radio frequency ladder filter including a plurality of series arm surface acoustic wave resonators electrically connected in series between an input of the filter and an output of the filter, and a plurality of shunt surface acoustic wave resonators each electrically connected between nodes between adjacent one of the plurality of series arm surface acoustic wave resonators and ground, one or more of the plurality of series arm surface acoustic wave resonators including gap hammer structures, a remaining one or more of the plurality of series arm surface acoustic wave resonators lacking gap hammer structures to improve insertion loss characteristics of the filter.

10. The electronics module of claim 9 wherein one or more of the plurality of shunt surface acoustic wave resonators include gap hammer structures.

11. The electronics module of claim 10 wherein each of the plurality of shunt surface acoustic wave resonators include gap hammer structures.

12. The electronics module of claim 9 wherein one of the plurality of series arm surface acoustic wave resonators has a resonance frequency lower than another of the plurality of series arm surface acoustic wave resonators, the one of the plurality of series arm surface acoustic wave resonators including the gap hammer structure, the another of the plurality of series arm surface acoustic wave resonators lacking the gap hammer structure.

13. The electronics module filter of claim 9 wherein the plurality of series arm surface acoustic wave resonators have a respective plurality of resonance frequencies, at least one of the plurality of series arm surface acoustic wave resonators having a lower resonance frequency than at least one other of the plurality of series arm surface acoustic wave resonators including the gap hammer structure.

14. The electronics module of claim 13 wherein a series arm surface acoustic wave resonator having a lowest resonance frequency among the plurality of series arm surface acoustic wave resonators includes the gap hammer structure.

15. The electronics module of claim 13 wherein a series arm surface acoustic wave resonator having a highest resonance frequency among the plurality of series arm surface acoustic wave resonators lacks the gap hammer structure.

16. The electronics module of claim 13 wherein a plurality of series arm surface acoustic wave resonators having lower resonance frequencies than a series arm surface acoustic wave resonators having a highest resonance frequency among the plurality of series arm surface acoustic wave resonators include the gap hammer structure.

17. A method of forming a radio frequency ladder filter, the method comprising:
forming a plurality of surface acoustic waver resonators, one or more of the surface acoustic wave resonators including a gap hammer structure, one or more other of the surface acoustic wave resonators lacking a gap hammer structure;
electrically connecting a first subset of the plurality of surface acoustic wave resonators in series between an input and an output of the filter, at least one of the first subset of the plurality of surface acoustic wave resonators lacking the gap hammer structure; and
electrically connecting a second subset of the plurality of surface acoustic wave resonators between nodes between adjacent one of the first subset of the plurality of series arm surface acoustic wave resonators and ground.

18. The method of claim 17 wherein at least one of the second subset of the plurality of surface acoustic wave resonators includes a gap hammer structure.

19. The method of claim 17 wherein at least one of the first subset of the plurality of surface acoustic wave resonators having a resonance frequency lowest among the first subset of the plurality of surface acoustic wave resonators includes a gap hammer structure.

20. The method of claim 17 wherein at least one of the first subset of the plurality of surface acoustic wave resonators having a resonance frequency highest among the first subset of the plurality of surface acoustic wave resonators lacks a gap hammer structure.
